(19) United States
(12) Patent Application Publication
(10) Pub. No.: US 2026/0182074 A1
(43) Pub. Date: Jun. 25, 2026

(54) VERTICAL TRANSFER GATE FOR IMAGE SENSOR

(71) Applicant: OMNIVISION TECHNOLOGIES, INC., Santa Clara, CA (US)

(72) Inventors: Ryuji Tomita, Utsukushigaoka (JP); Satoshi Nakayama, Sagami-ono Minami-Ku (JP); Ikuko Inoue, Kuden-cho (JP)

(73) Assignee: OMNIVISION TECHNOLOGIES, INC., Santa Clara, CA (US)

(21) Appl. No.: 19/001,423

(22) Filed: Dec. 25, 2024

(51) Int. Cl. H10F 39/00; H10F 39/18

(52) U.S. Cl. CPC H10F 39/812; H10F 39/18; H10F 39/811

(57) ABSTRACT

A pixel included in an image sensor includes a semiconductor substrate, a dielectric layer, a photodiode, a floating diffusion and a vertical transfer gate. The dielectric layer is disposed on the semiconductor substrate. The photodiode is formed in the semiconductor substrate. The floating diffusion is formed in the semiconductor substrate and separated from the photodiode. The vertical transfer gate is disposed coupling the photodiode to the floating diffusion and further disposed extending from the dielectric layer a depth into in the semiconductor substrate, wherein the vertical transfer gate includes a conductive material and a gate dielectric surrounding the conductive material, and the gate dielectric is disposed in the semiconductor substrate and levelled with a surface of the semiconductor substrate.

### BACKGROUND

### Technical Field

The present disclosure relates to an image sensor including a vertical transfer gate for transferring electric charges from a photodiode to floating diffusion.

### Description of Related Art

Conventionally, image sensors that obtain image signals using photodiodes have been known. Such an image sensor divides one pixel into a plurality of sub-pixels in many cases, not one pixel for one photodiode. In this case, a photodiode is provided to each sub-pixel, so that a signal from the sub-pixel may be used for autofocus.

For example, U.S. Pat. No. 9,609,250 discloses the configuration in which one floating diffusion is provided with respect to four photodiodes, and the accumulated electric charge in each photodiode is transferred to the one floating diffusion as appropriate.

Here, the number of pixels needs to be increased in order to obtain a fine image, while there is also a demand for a small-sized image sensor. Accordingly, reducing the size of one pixel is desired.

There is a possibility that one pixel having a reduced size causes problems on a layout, such as a problem of an insufficient interval between an electrode of a transfer transistor and another wiring.

### SUMMARY

According to embodiments of the disclosure, a pixel included in an image sensor includes a semiconductor substrate, a dielectric layer, a photodiode, a floating diffusion and a vertical transfer gate. The dielectric layer is disposed on the semiconductor substrate. The photodiode is formed in the semiconductor substrate. The floating diffusion is formed in the semiconductor substrate and separated from the photodiode. The vertical transfer gate is disposed coupling the photodiode to the floating diffusion and further disposed extending from the dielectric layer a depth into in the semiconductor substrate, wherein the vertical transfer gate includes a conductive material and a gate dielectric surrounding the conductive material, and the gate dielectric is disposed in the semiconductor substrate and levelled with a surface of the semiconductor substrate.

In some embodiments, since the vertical transfer gate penetrates through the dielectric layer, the distance between the vertical transfer gate and the surrounding component in the dielectric layer may be maintained. Thus, the reliability and the performance of the image sensor including the vertical transfer gate may be improved.

### BRIEF DESCRIPTION OF THE DRAWINGS

FIG. 1A is a schematic diagram of an imaging system in accordance with some embodiments of the disclosure.

FIG. 1B is a schematic diagram of a pixel circuit in an imaging system in accordance with some embodiments of the disclosure.

FIG. 2A is a schematic diagram of an image sensor in accordance with some embodiments of the disclosure.

FIG. 2B is a cross-sectional view of an image sensor of FIG. 2A in accordance with some embodiments of the disclosure.

FIG. 3A is a schematic diagram of an image sensor in accordance with a comparative embodiment.

FIG. 3B is a cross-sectional view of an image sensor of FIG. 3A in accordance with a comparative embodiment.

FIGS. 4A to 4H are cross-sectional views of a manufacturing process of an image sensor in accordance with some embodiments of the disclosure.

FIGS. 5A to 5H are cross-sectional views of a manufacturing process of an image sensor in accordance with some embodiments of the disclosure.

FIG. 6 is a cross-sectional view of an image sensor in accordance with some embodiments of the disclosure.

FIG. 7 is a cross-sectional view of an image sensor in accordance with some embodiments of the disclosure.

FIG. 8 is a cross-sectional view of an image sensor in accordance with some embodiments of the disclosure.

FIG. 9 is a cross-sectional view of an image sensor in accordance with some embodiments of the disclosure.

### DESCRIPTION OF THE EMBODIMENTS

References throughout this specification to one implementation, an implementation, one embodiment, an embodiment, and/or the like means that a particular feature, structure, characteristic, and/or the like described in relation to a particular implementation and/or embodiment is included in at least one implementation and/or embodiment of claimed subject matter. Thus, appearances of such phrases, for example, in various places throughout this specification are not necessarily intended to refer to the same implementation and/or embodiment or to any one particular implementation and/or embodiment. Furthermore, it is to be understood that particular features, structures, characteristics, and/or the like described are capable of being combined in various ways in one or more implementations and/or embodiments and, therefore, are within intended claim scope. In general, of course, as has always been the case for the specification of a patent application, these and other issues have a potential to vary in a particular context of usage. In other words, throughout the disclosure, particular context of description and/or usage provides helpful guidance regarding reasonable inferences to be drawn; however, likewise, “in this context” in general without further qualification refers at least to the context of the present patent application.

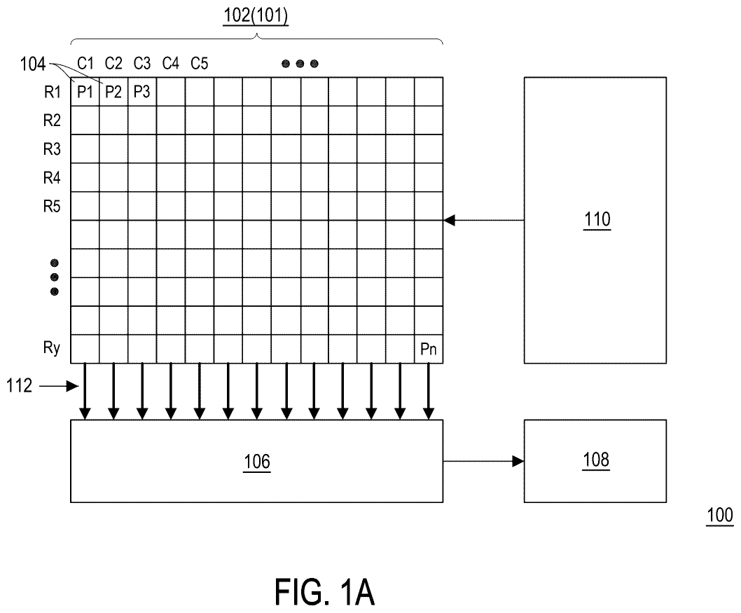

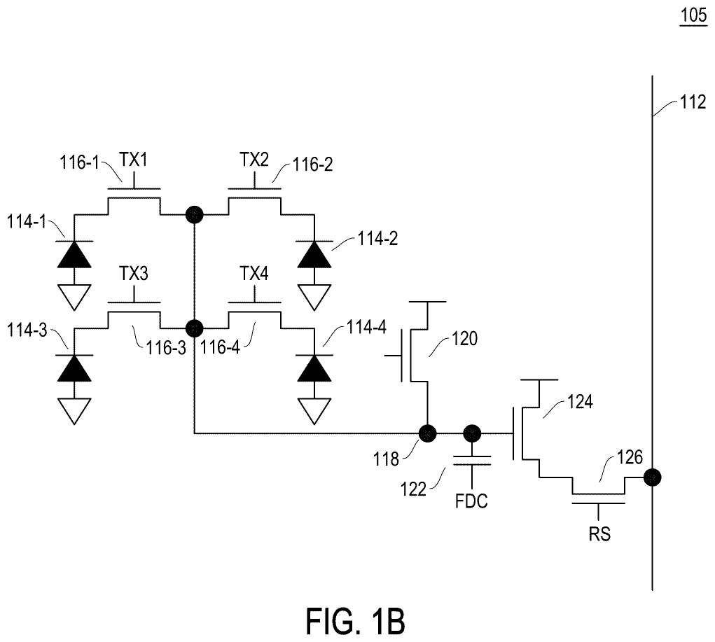

FIG. 1A is a schematic diagram of an imaging system in accordance with an embodiment of the disclosure. FIG. 1B is a schematic diagram of a pixel circuit in an imaging system in accordance with an embodiment of the disclosure.

Referring to FIG. 1A, an imaging system 100 includes a pixel array 102 of an image sensor 101, a control circuitry 110, a readout circuitry 106, and a function logic 108. The pixel array 102 may be a color pixel array. The image sensor 101 may be a backside illuminated sensor (BSI) and/or a solid state image sensor. The pixel array 102 includes a plurality of pixels 104. For example, the pixel array 102 is a two-dimensional (2D) array, and the pixels 104 are arranged into multiple rows (e.g., R1 to Ry) and multiple columns (e.g., C1 to Cx), to acquire an image data of a person, place, object or the like, which may then be used to render a 2D image of the person, place, object or the like. The pixel 104 may be or include an image sensor photodiode. The pixel 104 may include at least a vertical transfer gate structure coupled the image sensor photodiode for facilitating charge transfer between image sensor photodiode and a respective floating diffusion for image signal readout. As shown in FIG. 1A, the pixel array 102 includes photodiodes (e.g., P1, P2, P3 . . . , Pn), which include phase detection autofocus photodiodes interspersed among binned image sensing photodiodes. The phase detection autofocus photodiodes may provide phase detection information, which may be used for autofocus operations of the imaging system 100. As will be described below, in the same row of the pixel array 102, at least some of the transfer transistors coupled to the phase detection autofocus photodiodes may be controlled separately from the image sensing photodiodes.

In some embodiments, after each image sensor photodiode/pixel 104 in the pixel array 102 has acquired image charge or phase detection charge through photogeneration of the electric charges (e.g., electrons or holes), corresponding image data and/or phase detection charge is read out by the readout circuit 106 through bit lines 112 and then transferred to the function logic 108. The readout circuitry 106 may be coupled to read out data from the pixels 104 in the pixel array 102. In some embodiments, the readout circuitry 106 may include an amplification circuitry, an analog-to-digital (ADC) conversion circuitry, sample-and-hold circuitry, image buffers, or other circuitry components. For example, the readout circuitry 106 may read out a row of data at a time along the bit lines 112 as illustrated in FIG. 1A. The function logic 108 may store the image data or even manipulate the image data by applying post image effects (e.g., crop, rotate, remove red eye, adjust brightness, adjust contrast, or the like). The function logic 108 is coupled to the readout circuitry 106 to receive image data to de-mosaic the image data and generate one or more image frames. In some embodiments, the electrical signals and/or image data can be manipulated or otherwise processed by function logic 108 (e.g., apply post image effects such as crop, rotate, remove red eye, adjust brightness, adjust contrast, or otherwise).

It is appreciated that the term “photodiode” corresponds to a doped region (e.g., formed via implantation) disposed within or otherwise surrounded by an oppositely doped region to form a photosensitive area capable of photogenerating image charge in response to incident light. For example, as shown in FIG. 1B, photodiode 114-1 and/or photodiode 114-2 may correspond to an N-type semiconductor region (e.g., N-doped silicon region) disposed within a P-type semiconductor material (e.g., P-type doped silicon corresponding to semiconductor substrate or material). Accordingly, in some embodiments, photodiode 114-1, photodiode 114-2, photodiode 114-3, and photodiode 114-4 or other photodiodes included in embodiments of the disclosure each includes a doped region that is oppositely doped (e.g., opposite conductivity type) relative to a doping type of semiconductor substrate or material.

FIG. 1B may illustrate a pixel circuit 105 in the pixel array 102 of the imaging system 100 of FIG. 1A. The pixel circuit 105 may include a plurality of photodiodes 114 that coupled to transfer photo-generated images charges to a common floating diffusion via respective transfer transistor. Referring to FIG. 1B, the pixel circuit 105 may include a photodiode 114-1 (first photodiode) coupled to a transfer transistor 116-1 (or first transfer transistor 116-1), a photodiode 114-2 (second photodiode) coupled to a transfer transistor 116-2 (or second transfer transistor 116-2), a photodiode 114-3 or third photodiode coupled to a transfer transistor 116-3 (or third transfer transistor 116-3), and a photodiode 114-4 (or fourth photodiode) coupled to a transfer transistor 116-4 (or fourth transfer transistor 116-4). Each of the photodiodes 114-1˜114-4 is configured to couple to a floating diffusion 118 through respective transfer transistor 116-1, transfer transistor 116-2, transfer transistor 116-3, and transfer transistor 116-4. The transfer transistor 116-1, 116-2, 116-3, 116-4 may be also referred to as transfer transistor 116. In some embodiments, the pixel circuit 105 may further include an optional floating diffusion capacitance control signal FDC, and the optional floating diffusion capacitance control signal FDC may be coupled to a capacitor 122 which is coupled to the floating diffusion 118. As shown in FIG. 1B, the floating diffusion capacitance control signal FDC may be utilized to provide a boost control signal to the capacitor 122 coupled to the floating diffusion 118.

The transfer transistor 116-1 is coupled to be controlled in response to a transfer control signal TX1, the transfer transistor 116-2 is coupled to be controlled in response to a transfer control signal TX2, the transfer transistor 116-3 is coupled to be controlled in response to a transfer control signal TX3, and the transfer transistor 116-4 is coupled to be controlled in response to a transfer control signal TX4. As such, electric charges (e.g., electrons or holes) photogenerated in the photodiode 114-1 in response to an incident light are transferred to the floating diffusion 118 in response to the transfer control signal TX1 that turns on the transfer transistor 116-1, electric charges (e.g., electrons or holes) photogenerated in the photodiode 114-2 in response to an incident light are transferred to the floating diffusion 118 in response to the transfer control signal TX2 that turns on the transfer transistor 116-2, electric charges (e.g., electrons or holes) photogenerated in the photodiode 114-3 in response to an incident light are transferred to the floating diffusion 118 in response to the transfer control signal TX3 that turns on the transfer transistor 116-3, and electric charges (e.g., electrons) photogenerated in the photodiode 114-4 in response to an incident light are transferred to the floating diffusion 118 in response to the transfer control signal TX4 that turns on the transfer transistor 116-4.

As illustrated in FIG. 1B, a reset transistor 120 is coupled between a voltage supply (e.g., supply voltage AVDD) and the floating diffusion 118. A gate of a source follower (SF) transistor 124 is coupled to the floating diffusion 118. The drain of the source follower transistor 124 is coupled to a voltage supply (e.g., AVDD). In some embodiments, the drain of the source follower transistor 124 and the drain of reset transistor 120 may be coupled to a common voltage supply. In some embodiments, the drain of the source follower transistor 124 and the drain of reset transistor 120 may be coupled to receive supply voltage from different voltage supply. A row select transistor 126 is coupled to a source of the source follower transistor 124. In operation, the row select transistor 126 is coupled to output a data signal (e.g., image data or focus data) from the source follower transistor 124 of the pixel circuit 105 to the bit line 112 (shown in FIG. 1A) in response to a row select signal RS. The data signal is generated in response to amount of light sense or detect by photodiodes 114-1˜114-2.

In some embodiments, some or all of the photodiodes 114-1, 114-2, 114-3, and 114-4 may be configured as image sensing photodiodes included in a color pixel array (e.g., pixel array 102 of FIG. 1A). In such embodiments, the incident light to be directed to the photodiodes 114-1, 114-2, 114-3, and 114-4 is directed, for example by corresponding microlens, through respective color filters of a color filter array before reaching the photodiodes 114-1, 114-2, 114-3, and 114-4. The color filter array may be a Bayer color filter or the like, and thus the incident light may be directed through a red color filter, a green color filter, or a blue color filter before reaching the photodiodes 114-1, 114-2, 114-3, and 114-4 that are configured as image sensing photodiodes.

In some embodiments, some or all of the photodiodes 114-1, 114-2, 114-3, and 114-4 may be configured as phase detection autofocus photodiodes depending on the specific location of the pixel circuit 105 within the pixel array (e.g., pixel array 102 of FIG. 1A). In such embodiments, the incident light to be directed to the photodiodes 114-1, 114-2, 114-3, and 114-4 is directed through a microlens before reaching the respective photodiodes 114-1, 114-2, 114-3, and 114-4. However, the disclosure is not limited thereto. In some embodiments, the incident light to be directed to the photodiodes 114-1, 114-2, 114-3, and 114-4 may be directed through any suitable optical components rather than a color filter or a microlens.

In some embodiments, the plurality of photodiodes in the pixel array including photodiodes 114-1, 114-2, 114-3, and 114-4 are binned. As such, the information generated from each photodiode is summed with information generated from one or more nearby binned photodiodes to generate combined information, and therefore the performance of the pixel array may be improved by summing the performance of each individual photodiode. For example, 2×2 groupings of photodiodes (i.e., 4C cells) of same color are configured to be binned. In other words, the photodiodes included in the pixel array are arranged in manner that 2×2 groupings of image sensing photodiodes are of same color e.g., red, green, or blue. In the same or different embodiments, the 2×2 groupings of binned photodiodes are all adjacent photodiodes in the pixel array and share the same color filter. In some embodiments, the 2×2 groupings of binned photodiodes may all share the same color, but each two photodiodes that have the same color are separated from one another by another photodiode having a different color.

In some embodiments, the phase detection autofocus photodiodes are grouped into 2×2 groupings, which are interspersed among image sensing photodiodes of a color pixel array and share a microlens with the image sensing photodiodes. In some alternative embodiments, the phase detection autofocus photodiodes array are grouped into 2×1 groupings, which are interspersed among image sensing photodiodes of a color pixel array and share a microlens.

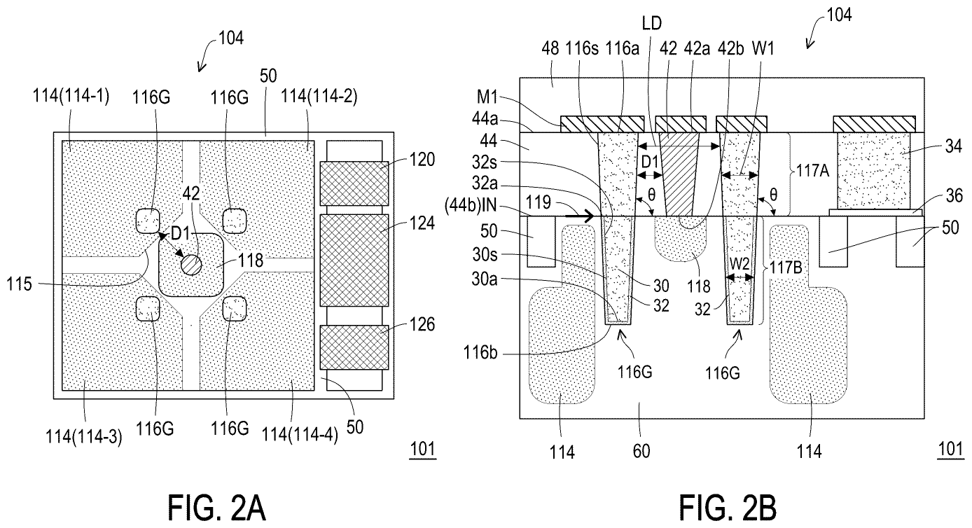

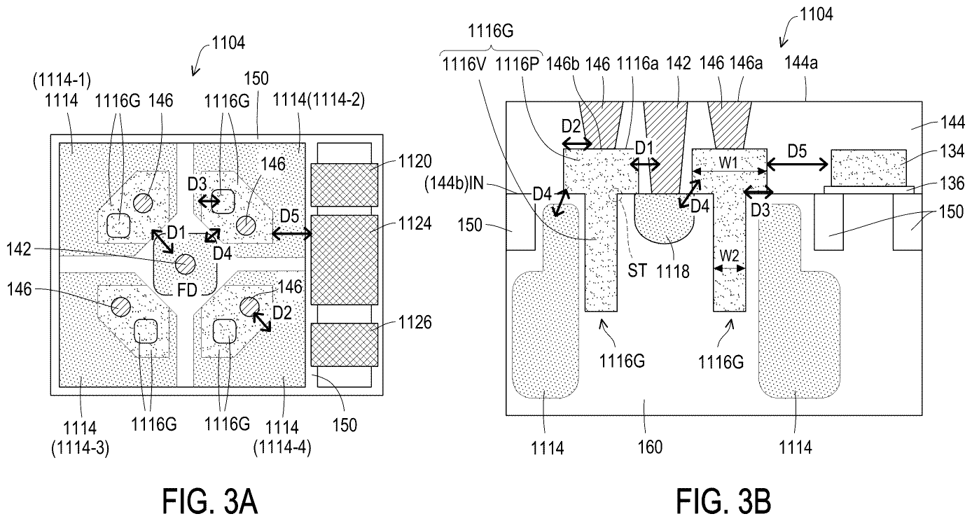

FIG. 2A is a schematic diagram of an image sensor in accordance with some embodiments of the disclosure. FIG. 2B is a cross-sectional view of an image sensor of FIG. 2A in accordance with some embodiments of the disclosure.

Referring to FIG. 2A, which provides a plane view (e.g., top view) of a pixel 104. In the exemplary layout illustrated in FIG. 2A, pixel 104 may have an approximately square shape, however it is appreciated that other layout shape configuration may be employed without departing from scope. The pixel 104 may be a pixel included in a pixel array of an image sensor 101 that includes a plurality of photodiodes, a plurality of vertical transferee gates and a floating diffusion 118. For example, in the illustrated embodiments, pixel 104 takes 2 by 2 configuration with four photodiodes 114 (e.g., photodiodes 114-1 to 114-4) are separately disposed in up, down, left, and right portions of the pixel 104. For example, photodiode 114-1 and photodiode 114-2 are arranged on the same row (first row) i.e., horizontally aligned and photodiode 114-3 and photodiode 114-4 are horizontally aligned arranged on the same row (second row) different form the first row. Photodiode 114-1 and photodiode 114-3 are vertically aligned or arranged on the same column (first column). Photodiode 114-2 and photodiode 114-4 are vertically aligned or arranged on the same column (second column). Each photodiode 114 generates electric charges (e.g., electrons or holes) in accordance with an incident light. In some embodiments, the photodiodes 114 are arranged in a region of the pixel 104. For example, the four photodiodes 114 illustrated in FIG. 2A are arranged into an array (e.g., 2×2 array) along a first lateral direction (e.g., x direction) and a second lateral direction (e.g., y direction) substantially perpendicular to the first lateral direction. The photodiodes 114 respectively have a cut corner 115, and the cut corners 115 together define a substrate region at the center of the region of the pixel 104. The substrate region in the illustrated embodiment has, for example, a diamond shape in a top view.

The floating diffusion 118 may be disposed in the substrate region and surrounded by the plurality of photodiodes 114. In the illustrated embodiment of 2 by 2 grouping, the floating diffusion 118 is surrounded by four photodiodes. The floating diffusion 118 is physically separated from the photodiodes 114. The floating diffusion 118 has, for example, a rectangular shape or any other suitable shape in a top view. However, it is appreciated that the resulting shape of the floating diffusion 118 depends on specific doping profile and pixel layout configuration, and shall not limit the present disclosure. A contact 42 may be disposed in contact with the floating diffusion 118 to couple the floating diffusion 118 to a gate electrode of source follower transistor for signal readout. The floating diffusion 118 is coupled to a plurality of transistors for taking out signals via the contact 42 and one or more metal interconnects included in metal wiring M1 (shown in FIG. 2B). In some embodiments, each of the plurality of vertical transfer gates 116G is disposed between each respective photodiodes 114 and floating diffusion 118. Each of the plurality of vertical transfer gates 116G may be disposed separating each respective photodiodes 114 and floating diffusion 118. Each of the plurality of vertical transfer gates 116G (e.g., four vertical transfer gates) are respectively disposed adjacent to and corresponding to the plurality of photodiodes (four photodiodes) 114. For example, each of the vertical transfer gates 116G in illustrated embodiments is respectively disposed adjacent to the cut corners 115 of the plurality of photodiodes 114, to be adjacent to the floating diffusion 118 to facilitate charge transfer between each respective photodiodes and the floating diffusion 118.

In some embodiments, transistors (e.g., a reset transistor (RST) 120, a source follower transistor (SF) 124, and a row select transistor (RS) 126) are disposed in a region for transistors allocated at one side (e.g., right side in FIG. 2A) of the region of the pixel 104. The transistors may be arranged in the second lateral direction (e.g., y direction). The transistors are used for reading out data signals. The region for the photodiodes 114 and the region for the transistors may be arranged in adjacent to each other, for example. The region for transistors may be arranged between adjacent pixels 104. A shallow trench isolation (STI) 50 is disposed to surround the pixel 104. In some embodiments, the STI 50 surrounds the region for having the plurality of photodiodes 114 and the region for the transistors respectively, and a portion of the STI 50 is disposed between the region for the photodiodes 114 and the region for the transistors providing isolation there between. In this manner, one pixel 104 is isolated from another adjacent pixel (not shown) by the STI 50, and the region for the photodiodes 114 is isolated from the region for the transistors.

Referring to FIG. 2B, the pixel 104 is disposed on a semiconductor substrate 60. A dielectric layer 44 is disposed on a surface of the semiconductor substrate 60. The dielectric layer 44 may be an interlayer dielectric (ILD). A metal wiring M1 is disposed on the dielectric layer 44, and the metal wiring M1 is covered with a passivation layer 48.

In some embodiments, the semiconductor substrate 60 includes or is otherwise formed of silicon (e.g., single crystal silicon), a silicon germanium alloy, germanium, silicon carbide (SiC), a silicon carbide alloy, an indium gallium arsenide alloy, any other alloys formed of III-V group compounds, combinations thereof, one or more epitaxial layers of the aforementioned materials, or a bulk substrate thereof. The semiconductor substrate 60 may include a plurality of doped regions therein to provide a P type region and an N type region, and thus the pixel 104 is formed. For example, the photodiode 114 in the semiconductor substrate 60 includes the N type region at a first side (e.g., front side) and the P type region at a second side (e.g., rear side) opposite to the first side. In some embodiments, the first side is also an interface IN of the semiconductor substrate 60 and the dielectric layer 44. The P type region at the second side (e.g., rear side) of the photodiode 114 may be coupled to the ground. Electric charges (e.g., electrons) are accumulated in the photodiode 114 corresponding to an incident light, and the accumulated electric charges are then transported to the floating diffusion 118 by the transfer transistor 116, for example.

The vertical transfer gate 116G is disposed between the photodiode 114 and the floating diffusion 118. The vertical transfer gate 116G controls the movement of the electric charges from the photodiode 114 to the floating diffusion 118 in response to an applied voltage. The vertical transfer gate 116G is disposed adjacent to the N type doped region at the first side (e.g., front side) of the photodiode 114. The vertical transfer gate 116G is a gate of the transfer transistor 116 that controls the transfer of electric charges from the photodiode 114 to the floating diffusion 118. In some embodiments, the vertical transfer gate 116G penetrates through the dielectric layer 44 and further extends into the semiconductor substrate 60. For example, the vertical transfer gate 116G extends between opposite surfaces 44a and 44b (e.g., top surface 44a and bottom surface 44b) of the dielectric layer 44 and further extends into the semiconductor substrate 60. The surface 44b is also the interface IN between the semiconductor substrate 60 (e.g., a surface of the semiconductor substrate 60 such as front side surface of the semiconductor substrate 60) and the dielectric layer 44.

The vertical transfer gate 116G may have a tubular shape, a pillar shape or a cylindrical shape in the dielectric layer 44 and the semiconductor substrate 60. In some embodiment as shown in FIG. 2B, an area (e.g., cross-sectional area in a plane parallel to font surface of the semiconductor substrate 60) of a first cross-sectional surface 116a of the vertical transfer gate 116G may be larger than an area (e.g., cross-sectional area in a plane parallel to font surface of the semiconductor substrate 60) of a second cross-sectional surface 116b of the vertical transfer gate 116G. The first cross-sectional surface 116a is also referred to as front surface, upper surface, upper end surface or the like of the vertical transfer gate 116G, and the second cross-sectional surface 116b is also referred to as rear surface, lower surface, lower end surface or the like of the vertical transfer gate 116G. An area of the vertical transfer gate 116G may be decreased graduate from first cross-sectional surface 116a to second cross-sectional surface 116b. The cross-sectional area decreases as the vertical transfer gate 116G extends from the dielectric layer 44 into the semiconductor substrate 60. For example, the area gradually changes from the first cross-sectional surface 116a to the second cross-sectional surface 116b, so that the vertical transfer gate 116G extends smoothly and continuously without a step profile. Also, the vertical transfer gate 116G is arranged to extend continuously through the dielectric layer 44 and into the semiconductor substrate 60 without a structural turning point or sharp width transition point. For example, the vertical transfer gate 116G is embedded within the dielectric layer 44 and extends into the semiconductor substrate 60. In some embodiments, the vertical transfer gate 116G has a tapered sidewall 116s continuously extending between the first cross-sectional surface 116a and the second cross-sectional surface 116b of the vertical transfer gate 116G. In some embodiments, the first cross-sectional surface 116a of the vertical transfer gate is levelled or coplanar with the top surface 44a of the dielectric layer 44.

In embodiments, the vertical transfer gate 116G includes a conductive material 30 and a gate dielectric 32. The conductive material 30 is disposed within regions of the semiconductor substrate 60 and the dielectric layer 44, and the gate dielectric 32 is disposed in the semiconductor substrate 60 without extending into the dielectric layer 44. In other words, the gate dielectric 32 is arranged to only surround a portion of the conductive material 30 within the semiconductor substrate 60. For example, the conductive material 30 includes a sidewall 30s and a bottom surface 30a in the semiconductor substrate 60, and the gate dielectric 32 surrounds the sidewall 30s and the bottom surface 30a of the conductive material 30. The gate dielectric 32 is disposed between the conductive material 30 and the semiconductor substrate 60 to electrically insulate the conductive material 30 and the semiconductor substrate 60. The gate dielectric 32 may be in direct contact with the semiconductor substrate 60, and the conductive material 30 may be in direct contact with the dielectric layer 44. An upper surface 32a of the gate dielectric 32 is substantially coplanar with the interface IN of the semiconductor substrate 60 and the dielectric layer 44, for example. The first cross-sectional surface 116a of the vertical transfer gate 116 is substantially coplanar with the top surface 44a of the dielectric layer 44. The interface IN of the semiconductor substrate 60 and the dielectric layer 44 is arranged between the first cross-sectional surface 116a and the second cross-sectional surface 116b of the vertical transfer gate 116G. A material of the conductive material 30 may include metal material such as tungsten or aluminum, polysilicon or a combination thereof or the like. The gate dielectric 32 includes silicon oxide, and is formed by thermal oxidation and the like.

In some embodiments, the vertical transfer gate 116G includes a first portion (e.g., upper portion) 117A in the dielectric layer 44 and a second portion (e.g., lower portion) 117B in the semiconductor substrate 60. The second portion 117B is physically or structurally connected to the first portion 117A. The first portion 117A and the second portion 117B are continuous without a structural turning point or sharp width transition point therebetween. As shown in FIG. 2B, there is no turning point or step profile at an interface 119 of the first portion 117A and the second portion 117B. The lateral width (e.g., diameter) W1, W2 may be in a range of 90 nm to 125 nm and decrease from the first cross-sectional surface 116a to the second cross-sectional surface 116b. The lateral width (e.g., diameter, cross-sectional width) W1 of the first portion 117A decreases as the first portion 117A becomes closer to the interface IN of the semiconductor substrate 60 and the dielectric layer 44. The lateral width (e.g., diameter, cross-sectional width) W2 of the second portion 117B decreases as the second portion 117B becomes away from the interface IN of the semiconductor substrate 60 and the dielectric layer 44. In some embodiments, the lateral width W1 of the first cross-sectional surface 116a may be configured in a manner (e.g., about 110-120 nm) such that an included angle θ formed between the second cross-sectional surface 116b and the sidewall 116s of the vertical transfer gate 116G may be in a range of 85 degrees to 90 degrees providing required cross-sectional area dimension. In some embodiments in which the thickness of the dielectric layer 44 is 300 nm to 330 nm, and the depth of the vertical transfer gate 116G extends in the semiconductor substrate 60 is 400-450 nm with respect to front side surface of the semiconductor substrate 60, the lateral width W2 of the second cross-sectional surface 116b is about 95 nm when the included angle θ is 89 degrees, and the lateral width W2 of the second cross-sectional surface 116b is about 70 nm when the included angle θ is 88 degrees. However, the disclosure is not limited thereto. The vertical transfer gate 116G may have any suitable lateral width and the included angle θ.

The first portion 117A of the vertical transfer gate 116G includes the conductive material 30 in the dielectric layer 44, and the second portion 117B of the vertical transfer gate 116G includes the conductive material 30 and the gate dielectric 32 surrounding the conductive material 30, for example. Surface (e.g., top surfaces) of the conductive material 30 and the dielectric layer 44 are substantially coplanar and higher than a surface (e.g., top surface) of the gate dielectric 32. A vertical thickness of first portion 117A of the vertical transfer gate 116G may be substantially the same as a layer thickness of dielectric layer 44. The second portion 117B of the vertical transfer gate 116G may extend a depth into the semiconductor substrate 60 with respect to a front side surface of semiconductor substrate 60.

The floating diffusion 118 is surrounded by the vertical transfer gates 116G. The floating diffusion 118 may be formed by doping the semiconductor substrate 60 with impurities, and the floating diffusion 118 functions as a capacitor having predetermined capacitance (e.g., as shown in FIG. 1B) for storing accumulated charges. The floating diffusion 118 is N type doped region, for example, that is opposite to that of the semiconductor substrate 60. Accordingly, in a case where the vertical transfer gate 116G receive a bias voltage at a high level, the surrounding substrate region of the vertical transfer gate 116G becomes N type forming transport channel, so that electric charges from the adjacent photodiode 114 move to the floating diffusion 118.

In some embodiments, as shown in FIG. 2B, the photodiodes 114 may include a first photodiode 114 (e.g., photodiode 114-1 located at left side of layout of pixel 104 in FIG. 2B) and a second photodiode 114 (e.g., photodiode 114-2 located at right side of layout of pixel 104 in FIG. 2B), and each of photodiodes 114-1 and 114-2 has a configuration as described above and has the transfer gate 116G between the photodiode 114 and the floating diffusion 118. The photodiodes 114 may extend from the dielectric layer 44 a same or different depth in the semiconductor substrate 60. A lateral distance LD between the vertical gate 116G (e.g., at left side of FIG. 2B) of the first photodiode 114 and the vertical gate 116G (e.g., at right side of FIG. 2B) of second photodiode 114 varies between the dielectric layer 44 and the surface IN of the semiconductor substrate 60. For example, the lateral distance LD may increase as closer to the cross-sectional surface 116b of the vertical transfer gates 116G.

The contact 42 is coupled to the floating diffusion 118, so that electric charges may be read out from the floating diffusion 118, and the floating diffusion 118 may be reset. For example, the contact 42 is disposed on the floating diffusion 118 and penetrates through the dielectric layer 44. In some embodiments, one end of the floating diffusion 118 is coupled to the contact 42, and the other end of the floating diffusion 118 is coupled to the ground or the like. In some embodiments, similar to the vertical transfer gate 116G, the contact 42 may also include a tubular shape, a pillar shape or a cylindrical shape that is tapered downwardly. The lateral width of the contact 42 may be in a range of 45 nm to 65 nm and decrease from a first surface (e.g., upper surface) 42a to a second surface (e.g., lower surface) 42b. For example, the lateral width of the first surface 42a of the contact 42 is about 60 nm, and the lateral width of the second surface 42b of the contact 42 that is in direct contact with the floating diffusion 118 is about 40 nm. In some embodiments, a distance D1 between the vertical transfer gate 116G and the adjacent contact 42 may be configured in a range of 90 nm to 70 nm and increases in a direction from the first surface 42a to the second surface 42b of the contact 42. For example, the distance D1 between the second cross-sectional surface 116b of the vertical transfer gate 116G and the second surface 42b of the adjacent contact 42 is about 85 nm providing sufficient separation distance therebetwen.

In some embodiments, a gate electrode 34 of the transistor 120, 124, 126 is disposed on the semiconductor substrate 60 adjacent to the vertical transfer gate 116G. A gate insulating layer 36 may be disposed underneath the gate electrode 34 and in between the semiconductor substrate 60 and the gate electrode 34. In some embodiments, the gate electrode 34 may penetrate through the dielectric layer 44, to couple the metal wiring M1. In addition, the gate electrode 34 may further couple to other component through the metal wiring M1.

The metal wiring M1 is disposed on the dielectric layer 44 and coupled to the vertical transfer gate 116G to implement desired wiring. For example, the metal wiring M1 is disposed on the surface 44a of the dielectric layer 44 and in direct contact with the vertical transfer gate 116G. That is, the metal wiring M1 and the vertical transfer gate 116G may be in direct contact at the surface 44a of the dielectric layer 44. The metal wiring M1 may be or included in an interconnect structure and thus may be also referred to as an interconnect structure, an interconnect layer or the like. The metal wiring M1 may include a plurality of conductive layers and dielectric layers stacked alternately. In some embodiments, the metal wiring M1 is covered by the passivation layer 48.

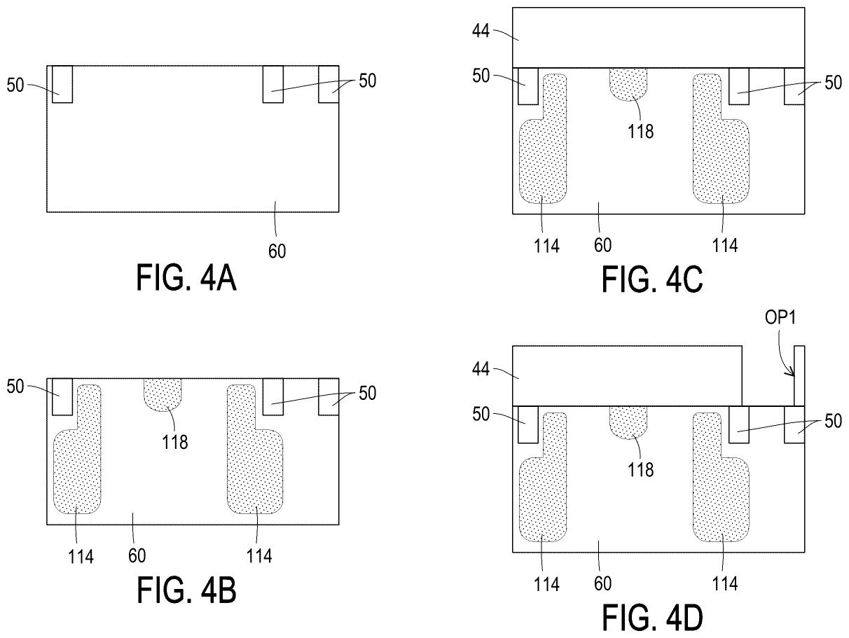

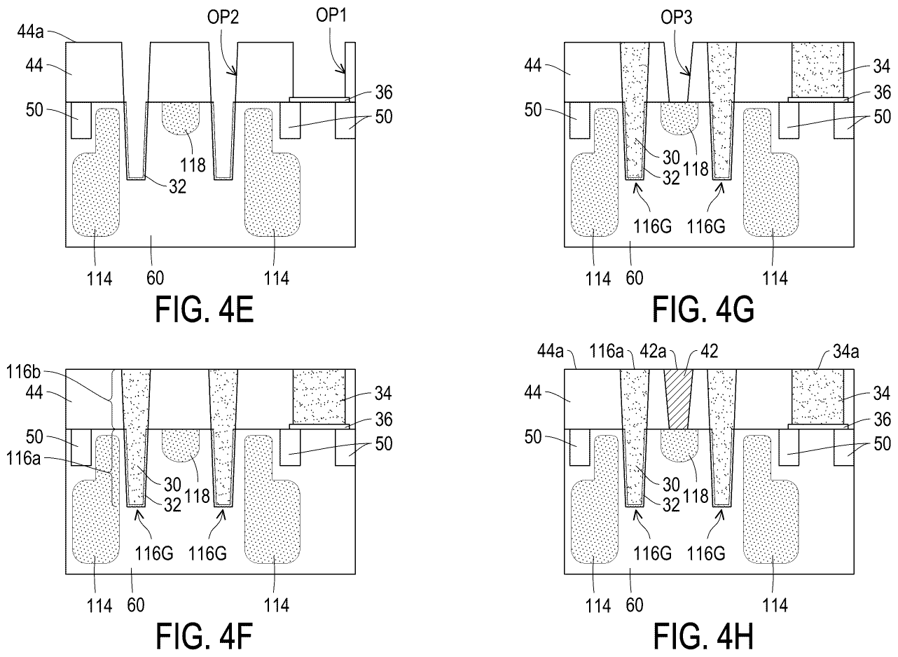

FIG. 3A is a schematic diagram of an image sensor in accordance with a comparative embodiment, and FIG. 3B is a cross-sectional view of an image sensor of FIG. 3A in accordance with a comparative embodiment. In the comparative embodiment, the transfer gate 1116G has a T-shape. That is, the transfer gate 1116G include a planar gate portion 1116P which spreads out (or extends) laterally on the front surface of the semiconductor substrate 160 in the lateral direction and a vertical gate portion 1116V on the planar gate portion 1116P. For example, the transfer gate 1116G has a cross-sectional area in the dielectric layer 144 larger than that in the semiconductor substrate 160. As shown in FIG. 3B, a lateral width W1 of the planar gate portion 1116P in the dielectric layer 144 is larger than a lateral width W2 of the vertical gate portion 1116V in the semiconductor substrate 160, and a step ST is formed between the planar gate portion 1116P in the dielectric layer 144 and the vertical gate portion 1116V in the semiconductor substrate 160.

Since the planar gate portion 1116P of the transfer gate 1116G laterally spreads out (or extends) in the dielectric layer 144, there may be design constraints related to the vertical gate portion 1116V and the planar gate portion 1116P. For example, a distance D1 between the planar gate portion 1116P and the contact 142 on the floating diffusion 1118 should be kept, to avoid the contact and short between the planar gate portion 1116P and the contact 142. A minimum width D2 of the planar gate portion 1116P should be kept for avoiding the contact 146 on the planar gate portion 1116P from off-landing on the planar gate portion 1116P, which makes short between the contact 146 and the floating diffusion 1118 (or the photodiode 1114). A width D3 of the planar gate portion 1116P should be kept for avoiding a top of the vertical gate portion 1116V from exposing or disconnecting the vertical gate portion 1116V to the planar gate portion 1116P during the etch process for the planar gate portion 1116P. A distance D4 between the planar gate portion 1116P and the floating diffusion 1118 (or the photodiode 1114) should be kept, to avoid gate induced drain leakage (GIDL) or gate induced source leakage (GISL), which may also referred as issue with superleaky). A distance D5 between the planar gate portion 1116P and the gate electrode 134 of the transistor should be kept, to avoid short. Due to the pitch shrink, it is difficult for keeping enough distances D1, D4, and D5 and widths D2 and D3, which could lead various issues including short circuit with contact to floating diffusion 1118, superleaky (e.g., drain leakage), and off-landing contact to the planar gate portion 1116P.

The planar gate portion 1116P spreads in this manner for increasing the area of the first cross-sectional surface 1116a of the transfer gate 1116G. For example, a contact 146 is stacked on the transfer gate 1116G, and a lower end surface 146b of the contact 146 is coupled to the first cross-sectional surface 1116a of the transfer gate 1116G. An upper surface 146a of contact 146 may be coplanar with the top surface 144a of dielectric layer 144. As shown in FIG. 3B, the first cross-sectional surface 1116a of the transfer gate 1116G may be larger than the lower end surface 146b of the contact 146. Thus, a margin by the distance D2 is generated when the lower end surface 146b of the contact 146 is coupled to the first cross-sectional surface 1116a of the transfer gate 1116G. The margin is defined as a distance between a periphery of the first cross-sectional surface 1116a of the transfer gate 1116G and a periphery of the lower end surface 146b of the contact 146.

On contrary, in some embodiments of the disclosure, as shown in FIG. 2B, the vertical transfer gate 116G extends upwardly without a step profile. Accordingly, the dimension of area of the first cross-sectional surface 116a located in the dielectric layer 44 may be uniformly maintained in a predetermined range, and a distance (e.g., space, separation) between the vertical transfer gate 116G and the adjacent components such as the contact 42 and the gate electrode 34 may be also controlled in a desired range. Furthermore, in some embodiments of the disclosure, since the vertical transfer gate 116G may be directly connected to other component such as the metal wiring M1 as shown in FIG. 2B, the contact 146 of FIGS. 3A and 3B is unnecessary and may be omitted. Thus, it is not required to consider a position shift when coupling the contact 146 to the transfer gate 1116G

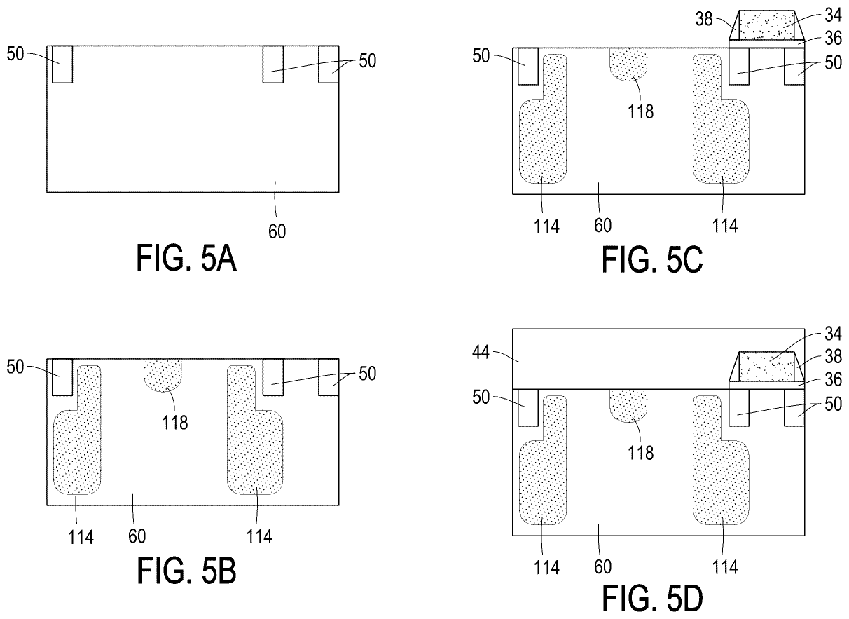

FIGS. 4A to 4H are cross-sectional views of a manufacturing process of an image sensor in accordance with some embodiments of the disclosure.

Referring to FIG. 4A, first, the shallow trench isolations 50 are formed on the semiconductor substrate 60. This may be conducted by a trench formation method. For example, a mask (not shown) having a predetermined shape is formed on the surface of the semiconductor substrate 60 to form a trench having a set depth by anisotropy etching. Next, the formed trench is filled with an insulating material such as silicon nitride or silicon oxide. In alternative embodiments, before filling the insulating material, an insulating lining layer is formed on a surface of the trench. In other embodiments, the shallow trench isolations 50 may be formed by forming an insulating lining layer on a surface of the trench and filling the trench with polysilicon material or suitable conductive material and kept at a predetermined potential.

Referring to FIG. 4B, next, the photodiodes 114 and the floating diffusion 118 are formed in the semiconductor substrate 60. For example, the photodiodes 114 and the floating diffusion 118 are formed between the by impurity doping the semiconductor substrate 60 such as N-type impurity to formed doped regions in the semiconductor substrate 60 disposed in a pixel region defined by the shallow trench isolations 50.

Referring to FIG. 4C, the dielectric layer 44 is formed on the surface (e.g., front side) of the semiconductor substrate 60. For example, silicon oxide material or the like is deposited on the surface of the semiconductor substrate 60 to form the dielectric layer 44 through various deposition scheme such as chemical vapor deposition. The surface is also the interface between the semiconductor substrate 60 and the dielectric layer 44.

Referring to FIG. 4D, an opening OP1 (e.g., vertical hole or trench) for the gate electrode 34 is formed by patterning the dielectric layer 44. For example, a portion of the dielectric layer 44 is removed by a lithography process including an etching process. The opening OP1 is formed at a predetermined location for the gate electrode to be formed. Thus, the opening OP is also referred to as pixel gate opening.

Referring to FIG. 4E, an opening OP2 for the vertical transfer gate 116G is formed by patterning the dielectric layer 44 and the semiconductor substrate 60. For example, portions of the dielectric layer 44 and the semiconductor substrate 60 are removed by a lithography process including an etching process. In some embodiments, as shown in FIG. 4E, a plurality of openings OP2 are formed in the dielectric layer 44 and the semiconductor substrate 60. The opening OP2 continuously extends from the surface (e.g., top surface) 44a of the dielectric layer 44 a depth into the semiconductor substrate 60.

Then, the gate dielectric 32 is formed lining sidewalls and bottom of the opening OP2 in the semiconductor substrate 60. The gate dielectric 32 is silicon oxide and is formed by thermal oxidation, for example. In some embodiments, since the semiconductor substrate 60 includes silicon, the thermal oxidation is performed on a portion of the semiconductor substrate 60 exposed by the opening OP2. Thus, the gate dielectric 32 only forms on sidewalls of the opening OP2 in the semiconductor substrate 60, and does not form on sidewalls of the opening OP2 in the dielectric layer 44. As shown in FIG. 4E, the gate dielectric 32 is formed only on a sidewall and a bottom surface of the opening OP2 surrounded by and contacting the semiconductor substrate 60. In some embodiments, the gate insulating layer 36 is formed on a bottom surface of the opening OP1 exposing the semiconductor substrate 60. The gate insulating layer 36 is silicon oxide and is formed by thermal oxidation, for example.

Referring to FIG. 4F, the opening OP2 is filled with the conductive material 30. The conductive material 30 and the gate dielectric 32 collectively form the vertical transfer gate 116G. In addition, the gate electrode 34 is formed in the opening OP1. In some embodiments in which the gate electrode 34 and the conductive material 30 of the vertical transfer gate 116G have the same material (e.g., polysilicon), the gate electrode 34 may be formed simultaneously with the conductive material 30 of the vertical transfer gate 116G by a same process. For example, a conductive material such as polysilicon is formed in the openings OP1, OP2, and then the excess conductive material outside the openings OP1, OP2 is removed by a chemical mechanical polishing process (CMP).

Referring to FIG. 4G, an opening (e.g., contact hole) OP3 for the contact 42 is formed by patterning the dielectric layer 44. For example, a portion of the dielectric layer 44 is removed by a lithography process including an etching process. The contact 42 exposes a portion of the floating diffusion 118.

Referring to FIG. 4H, the contact 42 is formed in the opening OP3. For example, a conductive material such as metal is formed in the opening OP3, and then the excess conductive material outside the opening OP3 is removed by a chemical mechanical polishing process (CMP). As shown in FIG. 4H, surfaces (e.g., top surfaces) 116a, 34a, 42a, 44a of the vertical transfer gates 116G, the gate electrode 34, the contact 42 and the dielectric layer 44 are substantially coplanar, for example. In some embodiments, the manufacturing process for one pixel is complete.

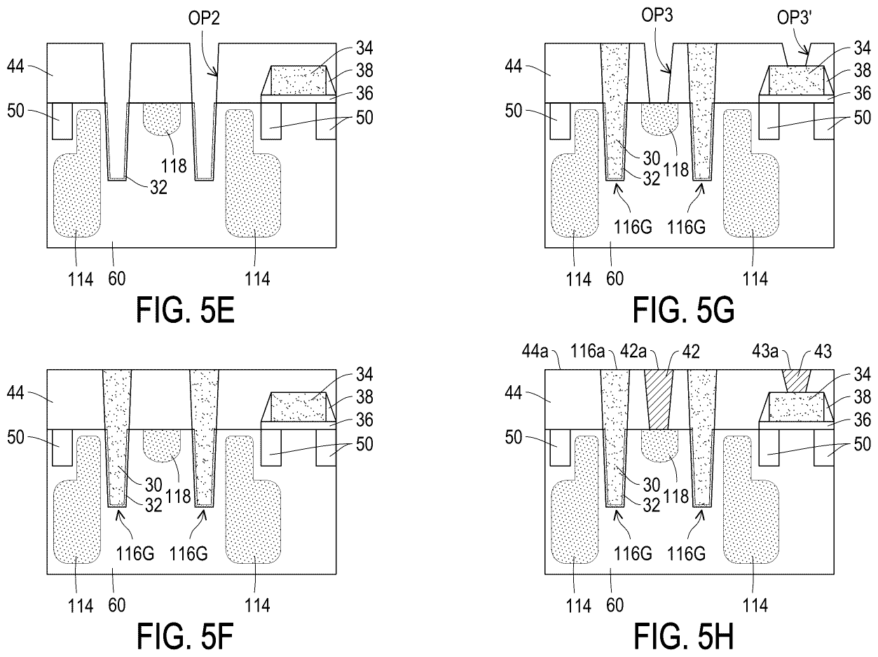

FIGS. 5A to 5H are cross-sectional views of a manufacturing process of an image sensor in accordance with some embodiments of the disclosure. The difference between the manufacturing process of FIGS. 5A to 5H and the manufacturing process of FIGS. 4A to 4H lies in the structure of the gate electrode 34.

Referring to FIGS. 5A and 5B, the steps of FIG. 5A and FIG. 5B are similar to the steps of FIG. 4A and FIG. 4B, and details thereof may be omitted. Referring to FIG. 5C, the gate electrodes 34 of the transistors (e.g., the reset transistor (RST) 120, the source follower transistor (SF) 124, and the row select transistor (RS) 126) are formed. For example, the gate insulating layer 36 is formed on the semiconductor substrate 60. Then, a conductive material such as polysilicon is deposited and patterned through a lithography process including an etching process, to form the gate electrodes 34 on the gate insulating layer 36. Thereafter, spacers 38 are formed alongside of the gate electrode 34. For example, the spacers 38 are disposed on opposite sidewalls of the gate electrode 34. It is noted that for clarity, only one gate electrode 34 is illustrated in FIG. 5C.

Referring to FIG. 5D, the dielectric layer 44 is formed to cover the gate electrodes 34. The material and forming method of the dielectric layer 44 are similar to those of FIG. 4C, and details thereof may be omitted.

Referring to FIG. 5E, openings (e.g., vertical vias, vertical cavity or trenches) OP2 for the vertical transfer gates 116G are formed in the semiconductor substrate 60, and the gate dielectric 32 is formed lining sidewalls and bottom of the opening OP2 in the semiconductor substrate 60. The forming method of the openings OP2 and the material and forming method of the gate dielectric 32 are similar to those of FIG. 4E, and details thereof may be omitted.

Referring to FIG. 5F, the openings OP2 are filled with the conductive material 30. The material and forming method of the conductive material 30 are similar to those of FIG. 4F, and details thereof may be omitted. The conductive material 30 and the gate dielectric 32 form the vertical transfer gate 116G. In some embodiments, since the conductive material 30 of the vertical transfer gate 116G and the gate electrode 34 are formed separately by different process, for example, the conductive material 30 is formed after the gate electrode 34, the conductive material 30 of the vertical transfer gate 116G and the gate electrode 34 may have different materials or the same material.

Referring to FIG. 5G, openings (e.g., contact holes) OP3, OP3′ are formed on the floating diffusion 118 and the gate electrode 34 by patterning the dielectric layer 44. For example, portions of the dielectric layer 44 are removed by a lithography process including an etching process to expose the floating diffusion 118 and the gate electrode 34.

Referring to FIG. 5H, the contacts 42, 43 are formed in the openings (e.g., contact holes) OP3, OP3′. The material and forming method of the contacts 42, 43 are similar to those in FIG. 4H, and details thereof may be omitted. As shown in FIG. 5H, surfaces (e.g., top surfaces) 42a, 43a, 116a, 44a of the vertical transfer gates 116G, the contacts 42, 43 and the dielectric layer 44 are substantially coplanar, for example.

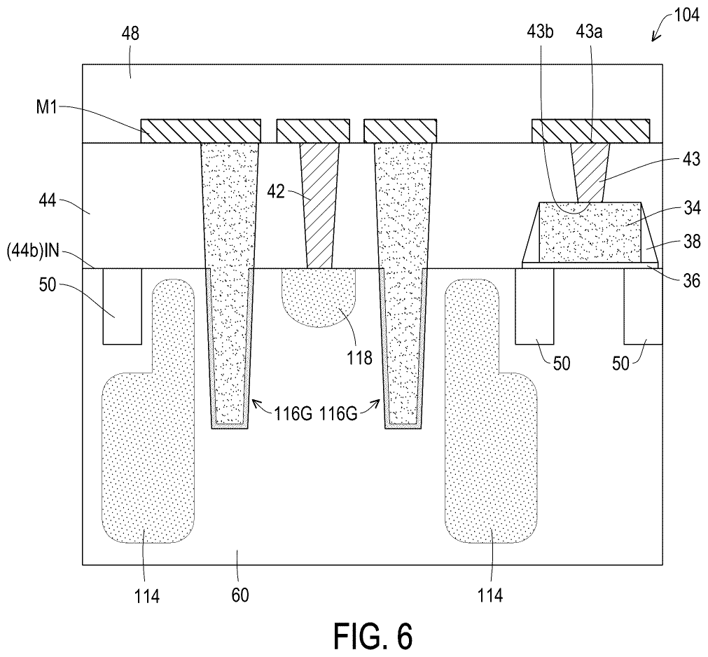

FIG. 6 is a cross-sectional view of an image sensor in accordance with some embodiments of the disclosure. The pixel of FIG. 6 may be formed by the process of FIG. 5A to FIG. 5H and have a structure similar to that of FIGS. 2A and 2B, the difference lies in the profile of the contact 43.

Referring to FIG. 6, the contact 43 has a shape similar to the vertical transfer gate 116G and the contact 42, for example, the contact 43 may have a tubular shape, a pillar shape or a cylindrical shape that is tapered downwardly. The lateral width may be in a range of 45 nm to 65 nm and decrease from the first surface 43a to the second surface 43b. The contact 43 is disposed in the dielectric layer 44. In some embodiments, the contact 43 is disposed between the gate electrode 34 and the metal wiring M1 and couples the gate electrode 34 of the transistors 120, 124, 126 to the metal wiring M1.

In some embodiments, as shown in FIG. 2B and FIG. 6, the vertical transfer gate 116G may have a desired lateral width. On contrary, in the comparative embodiment of FIG. 3, the lateral width of the first cross-sectional surface 116a of the vertical transfer gate 116G is about 271 nm, which is much larger than the lateral width of the first cross-sectional surface 116a of the vertical transfer gate 116G in FIG. 2B or FIG. 6. Thus, in a given area for the pixel, a distance between the vertical transfer gate 116G and the adjacent contact 42 is not sufficient that could lead to leakage and short circuit issues. In other words, the pixel having the configuration of FIG. 2B or FIG. 6 may have a compact layout.

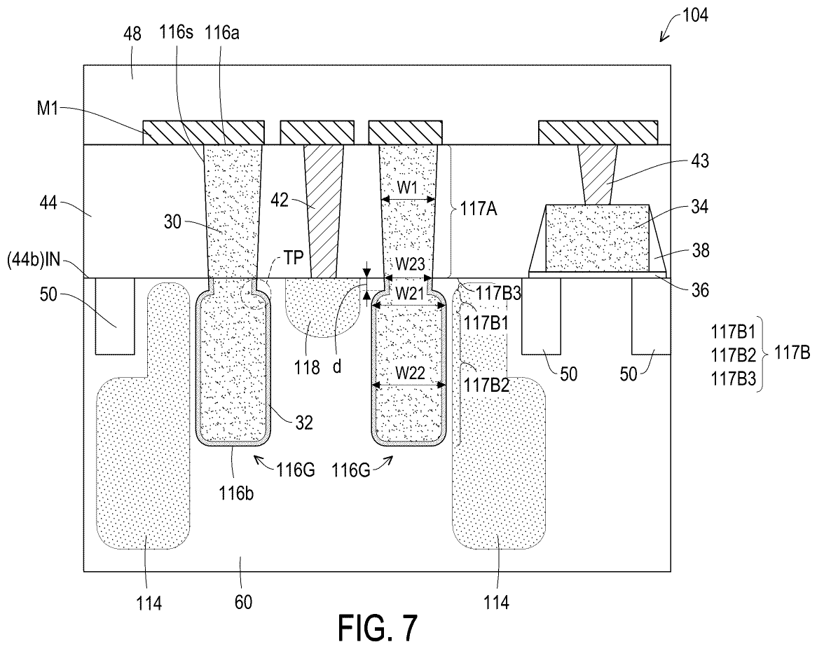

FIG. 7 is a cross-sectional view of an image sensor in accordance with some embodiments of the disclosure. The pixel of FIG. 7 may be similar to that of FIGS. 2A and 2B and FIF. 6, the difference lies in the profile of the vertical transfer gate 116G.

Referring to FIG. 7, the lateral width of the vertical transfer gate 116G is enlarged in the semiconductor substrate 60. For example, the vertical transfer gate 116G is bottle-shaped. In some embodiments, the vertical transfer gate 116G includes a first portion (e.g., upper portion) 117A in the dielectric layer 44 and a second portion (e.g., lower portion) 117B in the semiconductor substrate 60, and a turning point or lateral width transition point TN is formed adjacent to the interface IN of the semiconductor substrate 60 and the dielectric layer 44. For example, the turning point or lateral width transition point TN is formed below the interface IN of the semiconductor substrate 60 and the dielectric layer 44 and distant from the interface IN by a distance d. The second portion 117B is physically or structurally connected to the first portion 117A. The first portion 117A may have a tapered sidewall, and the lateral width (e.g., diameter) W1 of the first portion 117A decreases as the first portion 117A becomes closer to the interface IN of the semiconductor substrate 60 and the dielectric layer 44. For example, the lateral width W1 of the first cross-sectional surface 116a of the first portion 117A is about 120 nm, and the lateral width W1 of the first portion 117A at the interface IN of the first portion 117A and the semiconductor substrate 60 is smaller than 120 nm. The lateral width W1 of the first portion 117A is determined according to the included angle θ formed between the sidewall 116s of the first portion 117A and a surface of the semiconductor substrate 60 (also the interface IN of the semiconductor substrate 60 and the dielectric layer 44). The second portion 117B has a first section 117B1 with a variable lateral width W21, a second section 117B2 with a first substantially constant (uniformly) lateral width W22 and a third section 117B3 with a second substantially constant (uniformly) lateral width W23. The third section 117B3 is disposed between and in direct contact with the first portion 117A and the first section 117B1. The variable lateral width W21 of the first section 117B1 increase as the first section 117B1 becomes closer to the second section 117B2. The second portion 117B includes the gate dielectric 32. That is, each of the first section 117B1, the second section 117B2 and the third section 117B3 includes the gate dielectric 32 and the conductive material 30.

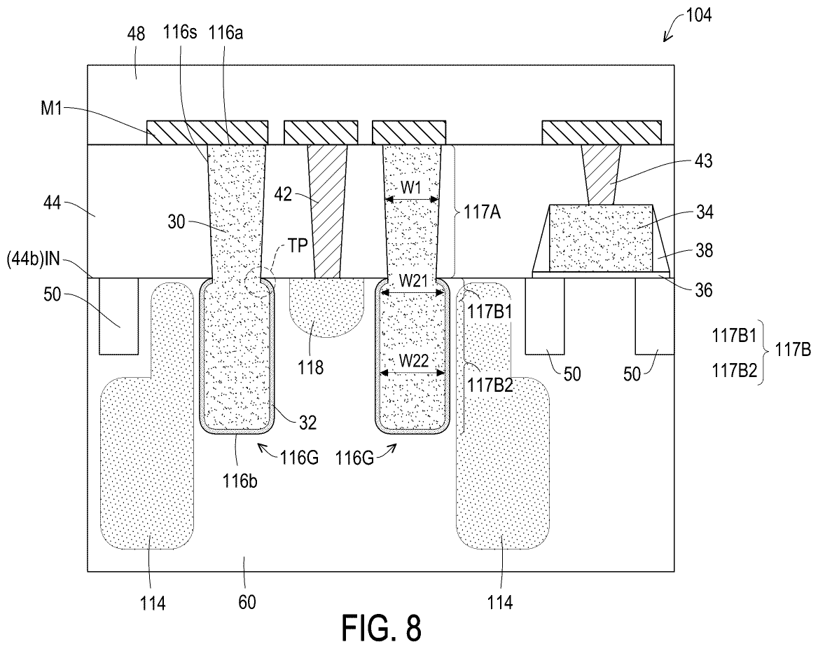

In alternative embodiments, as shown in FIG. 8, the third section 117B3 may be omitted, that is, the first section 117B1 is in direct contact with the first portion 117A. In the above embodiments such as shown in FIG. 7 and FIG. 8, the vertical transfer gate 116G is enlarged in the semiconductor substrate 60. A turning point or lateral width transition point TN is formed at the interface IN of the semiconductor substrate 60 and the dielectric layer 44. Accordingly, in some embodiments of FIG. 7 and FIG. 8, the lateral width of the second cross-sectional surface 116b of the vertical transfer gate 116G may be made large while a distance between the vertical transfer gate 116G in the dielectric layer 44 and the adjacent contact 42 is maintained equivalent to that in the abovementioned embodiments of FIG. 2B an FIG. 6. Accordingly, the profile of the vertical transfer gate 116G is suitable when the larger lateral width of the second cross-sectional surface 116b of the vertical transfer gate 116G is needed.

In some embodiments, the vertical transfer gate 116G may be formed by etching an opening in the dielectric layer 44 to expose the semiconductor substrate 60 and then isotropically etching the semiconductor substrate 60 through the opening. In other words, since the material of the dielectric layer 44 is different from the material of the semiconductor substrate 60, only the semiconductor substrate 60 is isotropically etched while the dielectric layer 44 is substantially intact without being etched. Accordingly, the first portion 117A of the vertical transfer gate 116G in FIG. 7 and FIG. 8 has the same profile as the first portion 117A of the vertical transfer gate 116G in FIG. 2B, and the second portion 117B of the vertical transfer gate 116G in FIG. 7 and FIG. 8 has different profile (e.g., bottom enlarged profile) from the second portion 117B of the vertical transfer gate 116G in FIG. 2B

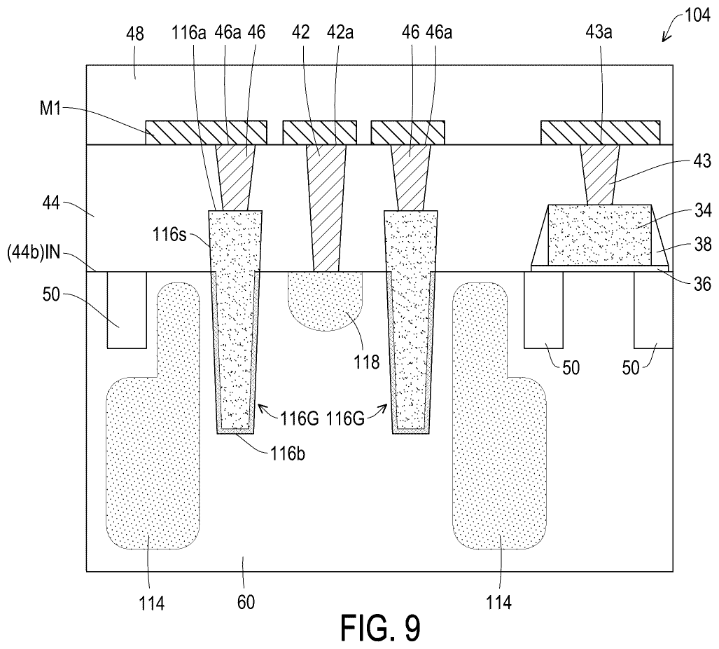

FIG. 9 is a cross-sectional view of an image sensor in accordance with some embodiments of the disclosure. Referring to FIG. 9, a second cross-sectional surface (e.g., top surface) 116b of the vertical transfer gate 116G is between opposite surfaces (e.g., top surface and bottom surface) 44a, 44b of the dielectric layer 44. For example, the second cross-sectional surface (e.g., top surface) 116b of the vertical transfer gate 116G is lower than the surface (e.g., top surface) 44b of the dielectric layer 44. In some embodiments, a contact 46 is disposed in the dielectric layer 44 extending from the surface 44a of dielectric layer 44 to first cross-sectional surface 116a of the vertical transfer gate 116G. The contact 46 is vertically stacked on vertical transfer gate 116G. The contact 46 may be coupled the vertical transfer gate 116G to corresponding metal interconnect of metal wiring M1 for vertical transfer gate 116G to receive control or bias voltage for transfer operation. The contact 46 may be overlapped with the vertical transfer gate 116G, and the contact 46 may be disposed between and in direct contact with the vertical transfer gate 116G and the metal wiring M1. For example, a lower or bottom surface of the contact 46 may in contact with an upper or top surface 116a of vertical transfer gate 116G. The contact 46 is entirely disposed in the dielectric layer 44. Surface (e.g., top or upper surfaces) 42a, 43a, 44a, 46a of the contact 46, the contact 42, the contact 43 and the dielectric layer 44 are substantially coplanar, and the first cross-sectional surface 116a of the vertical transfer gate 116G is disposed between the surface 44a of the dielectric layer 44 and the interface IN of the semiconductor substrate 60 and the dielectric layer 44. For example, the surface 44a of the dielectric layer 44 is higher than the first cross-sectional surface 116a of the vertical transfer gate 116G. A vertical distance exists between the surface 44a of the dielectric layer 44 and the first cross-sectional surface 116a of the vertical transfer gate 116. Alternatively, a combination height of the contact 46 and the portion of the vertical transfer gate 116 in the dielectric layer 44 is substantially equal to a layer thickness of the dielectric layer 44 The contact 46 may be formed simultaneously with the contact 42, 43. In some embodiments, the openings for the contact 46 and the contact 42, 43 are simultaneously formed in the dielectric layer 44, and then the contact 46, the contact 42 and the contact 43 are formed in the openings by filling a conductive material in the openings and removing excess conductive material outside the openings. In other words, the formation of the contact 46 is incorporated into the existing process and does not increase the process time and/or cost too much. In addition, in some embodiments in which the contact 46 is additionally provided, the area for the vertical transfer gate 116G may maintain without enlarging. Therefore, a desired distance may be kept between the vertical transfer gate 116G and the contact 43.

In some embodiments, the vertical transfer gate extends partially through the dielectric layer, the distance between the vertical transfer gate and the surrounding component in the dielectric layer may be maintained in a desired range and the freedom degree of the layout is improved. Furthermore, the reliability and the performance of the image sensor including the vertical transfer gate may be improved. In some embodiments, as shown in FIGS. 2A and 2B, since the vertical gate 116G is formed continuously from the top surface of the dielectric layer 44 into the semiconductor substrate 60 (i.e., a monolithic gate structure), an additional contact (e.g., contact 43 shown in FIG. 9) may be omitted. Thus, the manufacturing process may be simplified providing wider contact formation window for other components (e.g., contact to floating diffusion 118 and the occurrence of a shift between the contact 46 and the underlying vertical gate 116G is prevented since the contact 46 is not needed.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A pixel included in an image sensor, comprising:
a semiconductor substrate;
a dielectric layer, disposed on the semiconductor substrate;
a photodiode, formed in the semiconductor substrate;
a floating diffusion, formed in the semiconductor substrate and separated from the photodiode; and
a vertical transfer gate, disposed coupling the photodiode to the floating diffusion and further disposed extending from the dielectric layer a depth into in the semiconductor substrate, wherein the vertical transfer gate comprises a conductive material and a gate dielectric surrounding the conductive material, and the gate dielectric is disposed in the semiconductor substrate and levelled with a surface of the semiconductor substrate.

2. The pixel according to claim 1, wherein the vertical transfer gate comprises a tapered sidewall.

3. The pixel according to claim 1, wherein the vertical transfer gate is arranged to extend continuously through the dielectric layer and into the semiconductor substrate.

4. The pixel according to claim 1, wherein the gate dielectric is between the conductive material and the semiconductor substrate, and the conductive material is in a direct contact with the dielectric layer.

5. The pixel according to claim 1, wherein the vertical transfer gate is embedded within the dielectric layer.

6. The pixel according to claim 1, wherein the conductive material in the semiconductor substrate includes a sidewall and a bottom surface, and the gate dielectric is arranged to surround the sidewall and the bottom surface of the conductive material.

7. The pixel according to claim 1, wherein the vertical transfer gate has a first surface and a second surface opposite to the first surface, the first surface of the vertical transfer gate is substantially coplanar with a surface of the dielectric layer, and the surface of the semiconductor substrate, wherein the dielectric layer is disposed between the first surface and the second surface of the vertical transfer gate.

8. The pixel according to claim 7, wherein a first cross-sectional area of the first surface of the vertical transfer gate is larger than a second cross-sectional area of the second surface of the vertical transfer gate when viewed from a plan view.

9. The pixel according to claim 7, further comprising a gate electrode on the semiconductor substrate and a contact, wherein the contact is disposed on and coupled to the gate electrode, and a surface of the contact is substantially coplanar with the surface of the dielectric layer.

10. The pixel according to claim 7, further comprising a metal wiring, the metal wiring is disposed on the dielectric layer and extended to be in direct contact with the vertical transfer gate.

11. The pixel according to claim 1, further comprising a first contact, wherein the first contact is disposed in the dielectric layer, the first contact is stacked on and coupled to the vertical transfer gate, wherein a surface of the first contact is substantially coplanar with a surface of the dielectric layer, and a surface of the vertical transfer gate is disposed between the surface of the dielectric layer and the surface of the semiconductor substrate.

12. The pixel according to claim 11, further comprising a metal wiring, the metal wiring is disposed on the dielectric layer and in direct contact with the first contact.

13. The pixel according to claim 11, further comprising a gate electrode on the semiconductor substrate and a second contact, wherein the second contact is stacked on and coupled to the gate electrode, and a surface of the second contact is substantially coplanar with the surface of the dielectric layer.

14. The pixel according to claim 1, wherein the vertical transfer gate has a cross-sectional area that decreases as the vertical transfer gate extended from the dielectric layer into the semiconductor substrate.

15. The pixel according to claim 14, wherein:
the vertical transfer gate has a first portion in the dielectric layer and a second portion in the semiconductor substrate that is structurally connected to the first portion, wherein a cross-sectional width of the first portion decreases as the first portion becomes closer to the surface of the semiconductor substrate from the dielectric layer, and
the second portion has a first section with a variable cross-sectional width, a second section with a first substantially constant lateral width sectional and a third section with a second substantially uniformly cross-sectional width, and the third section is disposed between and in direct contact with the first portion and the first section.

16. The pixel according to claim 15, wherein the variable lateral width of the first section increase as the first section becomes closer to the second section.

17. The pixel according to claim 15, wherein the second portion comprises the gate dielectric disposed between the conductive material and the semiconductor substrate.

18. The pixel according to claim 14, wherein:
the vertical transfer gate has a first portion in the dielectric layer and a second portion in the semiconductor substrate that is structurally connected to the first portion, a cross-sectional width of the first portion decreases as the first portion becomes closer to the surface of the semiconductor substrate from the dielectric layer, and
the second portion has a first section with a variable cross-sectional width and a second section with a first substantially uniform cross-sectional width, and the first section is disposed between and in direct contact with the first portion and the second section.

19. The pixel according to claim 1, wherein the conductive material comprises polysilicon, and the gate dielectric comprises silicon oxide.

20. The pixel according to claim 1, further comprising:
a second photodiode, formed in the semiconductor substrate;
a second vertical transfer gate, disposed coupling the second photodiode to the floating diffusion and the second vertical transfer gate further disposed to extend from the dielectric layer a second depth into in the semiconductor substrate, wherein the second vertical transfer gate comprises a second conductive material and a second gate dielectric, and the second gate dielectric is disposed between the second conductive material and the semiconductor substrate, wherein a lateral distance between the vertical gate and the second vertical gate varies between the dielectric layer and the surface of the semiconductor substrate.
